(19) United States
(12) Patent Application Publication
(10) Pub. No.: US 2022/0148877 A1
(43) Pub. Date: May 12, 2022

(54) METHOD FOR SEMICONDUCTOR FILM LIFT-OFF AND SUBSTRATE TRANSFER

(71) Applicant: Yiguan information technology (Shanghai) Co., Ltd., Shanghai (CN)

(72) Inventor: Tao Jiang, Kunshan City (CN)

(21) Appl. No.: 17/580,066

(22) Filed: Jan. 20, 2022

Related U.S. Application Data
(63) Continuation of application No. PCT/CN2020/095312, filed on Jun. 10, 2020.

(30) Foreign Application Priority Data
Jul. 23, 2019 (CN) 201910668607X

(51) Int. Cl. H01L 21/02; H01L 21/78; H01L 21/306; H01L 21/683

(52) U.S. Cl. CPC H01L 21/02496; H01L 21/0262; H01L 21/02458; H01L 21/0254; H01L 21/7806; H01L 21/30612; H01L 21/6835; H01L 21/02376; H01L 21/02378; H01L 21/02381; H01L 21/02389; H01L 21/02395; H01L 21/0242; H01L 2221/68368; H01L 2221/6835; H01L 2221/68381; H01L 21/0243

(57) ABSTRACT

A method for semiconductor film lift-off and substrate transfer is provided. It includes: preparing a semiconductor film-substrate structure including a first substrate layer, multiple seed crystal structures and a semiconductor film layer stacked in that order, and holes are formed among the multiple seed crystal structures and communicated with one another; lifting-off the multiple seed crystal structures and the semiconductor film layer from the first substrate layer; and bonding a side of the multiple seed crystal structures facing away from the semiconductor film layer with a second substrate layer to complete processes of the semiconductor film lifting-off and the substrate transfer. The method can be compatible with various epitaxial substrate materials, and can also retain smooth surface of the device epitaxial layer film without affecting the subsequent process of growing other functional layers for preparing devices on the epitaxial layer film.

### FIELD OF THE DISCLOSURE

The disclosure relates to the field of semiconductor technologies, and more particularly to a method for semiconductor film lift-off and substrate transfer.

### BACKGROUND OF THE DISCLOSURE

The gallium nitride (GaN) material series mainly include GaN, boron nitride (BN) and alloy materials of aluminium gallium indium nitride (AlₓGa_{y}In_{1-x-y}N) (0≤x≤1, 0≤y≤1, 0≤x+y≤1). The GaN material series have low heat generation rates and high breakdown electric fields, which are important materials for developing high temperature and high-power electronic devices and high frequency microwave devices. Moreover, the GaN material series is also an ideal material for short-wavelength light-emitting devices, and the band gap of GaN and its alloy covers the spectral range from red to ultraviolet. Since Japan developed homojunction GaN blue light-emitting diode (LED) in 1991, indium gallium nitride (InGaN)/aluminium gallium nitride (AlGaN) double heterojunction ultra-bright blue LED and InGaN single quantum well GaN LED have been introduced one after another. Because of many excellent properties of the GaN material series, as one of the important semiconductor materials of the third-generation semiconductor, its research and application is the frontier and hotspot of global semiconductor research.

Although device level of the GaN material series can already be practical, the problem of single-crystal substrate has not been solved for a long time, the material film can only be obtained by heteroepitaxial process, and the density of heteroepitaxial defects is quite high, which has become the main obstacle to further enhance device performance. At present, the mainstream heteroepitaxial substrates are mainly sapphire and silicon carbide (SiC), and there are also commercial applications growing on silicon substrates, especially GaN LED technology based on sapphire substrates, which has been widely commercialized.

With the continuous development of the application scenarios of the GaN material series devices to high-power devices, due to the large amount of heat generated during device operation, if the heat cannot be transmitted in time, the devices will lead to performance degradation or even failure due to their own temperature increase. Therefore, the heat dissipation problem of the devices has always been an urgent problem to be solved. At present, there are generally two directions to solve the heat dissipation problem. One direction is to make improvement at the packaging level, using different packaging methods to export the heat generated by the device chip to the packaging heat dissipation substrate as quickly as possible, and the other direction is to make technical improvements at the device chip level, such as epitaxial substrate thinning of the chip to minimize the epitaxial substrate materials in non-device functional areas. For example, the semiconductor thin film material layer of the device is lifted-off from the original epitaxial substrate with poor thermal conductivity and transferred to the secondary support substrate with better thermal conductivity. These technical improvements based on the device chip level can more directly and effectively improve the heat dissipation capacity of the device, thus improving the stability and reliability of the device in high-power operation environment and even high-temperature environment. At present, the semiconductor film lifting-off and substrate transfer technology for device epitaxial layer mainly includes chemical mechanical grinding technology and laser lifting-off technology.

The chemical mechanical grinding technology is to adhere the smooth surface of the device epitaxial layer of the semiconductor wafer to a temporary support substrates such as copper (Cu), aluminum nitride (AlN), glass, silicon (Si) and SiC through epoxy resin, remove air bubbles in the resin in the vacuum environment, fix the temporary support substrate on the grinding disc, and the exposed surface is the original epitaxial substrate of the wafer. Then, the exposed surface of the epitaxial substrate is contacted on the grinding pad, the epitaxial substrate is chemically and mechanically ground by adding corrosive chemical abrasive and simultaneously rotating the grinding disc and the grinding pad until the epitaxial substrate is thinned to a certain extent. Subsequently, the temporary support substrate is soaked with organic solvent to separate the temporary support substrate from the thinned semiconductor wafer of the epitaxial substrate, restore the smooth surface of the epitaxial layer film of the device, and finally obtain the semiconductor wafer after the epitaxial substrate is thinned. Compared with the device without epitaxial substrate thinning, the thickness of the epitaxial substrate that is not the functional layer of the device but increases the thermal resistance is reduced, so it can obtain better thermal conductivity.

The chemical mechanical grinding technology has the advantages of stable process and low cost, but the disadvantage is that it is only applicable to epitaxial substrate materials whose chemical and physical properties are easier to handle, such as silicon (Si) material substrates, and for substrate materials with particularly stable physical and chemical properties, such as sapphire or SiC, the processing difficulty and cost will rise sharply, and the processing yield is difficult to guarantee. Further, the epitaxial substrate cannot be thinned indefinitely, otherwise it will bring great challenges to the subsequent device processing technology, which is easy to cause wafer breakage and reduce the device yield. Therefore, the devices processed by this technology will still have a certain thickness of epitaxial substrate materials with poor thermal conductivity, which limits the space for improving the device thermal conductivity.

The laser lifting-off technology is to evaporate metals, such as aluminium (Al), silver (Ag), nickel (Ni), chromium (Cr), gold (Au) and stannum (Sn), on the smooth surface of the device epitaxial layer of the semiconductor wafer, and adhere and fix the smooth surface of the device epitaxial layer with secondary support substrate such as Cu, aluminium nitride (AlN), Si and SiC by means of metal eutectic. Then, a certain power laser beam irradiates the semiconductor device epitaxial layer film from the back of the epitaxial substrate (i.e. the side without the device epitaxial layer film), and the energy of the laser will cause the decomposition of the semiconductor material at the connection between the epitaxial substrate and the device epitaxial layer film, so that the device epitaxial layer film is separated from the epitaxial substrate to obtain the device epitaxial layer film supported by the secondary support substrate with good thermal conductivity. Because the secondary support substrate with better thermal conductivity than the epitaxial substrate of the original semiconductor wafer can be used, the semiconductor wafer obtained by the laser lifting-off technology can obtain better device thermal conductivity when preparing the device.

The advantage of the laser lifting-off technology is that the epitaxial substrate with poor thermal conductivity can be completely lifted-off and replaced with the secondary support substrate having good thermal conductivity, and the thickness of the secondary support substrate can be adjusted as needed to avoid wafer breakage caused by subsequent device processing, thus maximizing the removal of epitaxial substrate material with poor thermal conductivity while ensuring device processing yields. However, the disadvantage is that due to the need to laser irradiation, this technology can only be applied to the irradiation of the laser beam transparent epitaxial substrate material, the selection of epitaxial substrate material has certain limitations, while the laser irradiation decomposition of the device epitaxial layer of thin film semiconductor material will generate a large amount of heat, these heat will also cause a certain degree of damage to the device, may lead to device performance degradation or even failure, thus affecting the yield rate and reliability of the device. Moreover, the smooth surface of semiconductor material obtained by epitaxy is also lost by the laser lifting-off technology. The ideal result of transferring the substrate is to directly replace the epitaxial substrate with the secondary support substrate material having good thermal conductivity while retaining the smooth surface of the device epitaxial layer film of the semiconductor wafer, so as to facilitate the subsequent device processing on the smooth surface of the device epitaxial layer film. However, this technology requires the secondary support substrate to be fixed on the smooth surface of the device epitaxial layer film of the semiconductor wafer at one time, and cannot use temporary support substrate and restore the smooth surface of the device epitaxial layer film after subsequent separation of the temporary support substrate. One reason is that a large amount of heat generated in the lifting-off process of this technology will make the temporary support substrate fall off, so only the permanently fixed secondary support substrate can be used. Therefore, the obtained device film cannot be further processed because the exposed surface is the contact surface between the device epitaxial layer film and the epitaxial substrate, which also limits the process space for device fabrication.

Therefore, the main problem existing in the lifting-off and transfer substrate of current GaN material series semiconductor film is that there is a certain thickness of epitaxial substrate material with poor thermal conductivity, which limits the space for improving the device thermal conductivity.

### SUMMARY OF THE DISCLOSURE

In order to solve the above problems in the related arts, the disclosure provides a method for semiconductor film lift-off and substrate transfer. The technical problems to be solved by the disclosure can be realized by following technical solutions.

In particular, a method for semiconductor film lift-off/stripping and substrate transfer exemplarily includes:

preparing a semiconductor film-substrate structure (also referred to as a semiconductor thin film-substrate structure), where the semiconductor film-substrate structure includes a first substrate layer, multiple seed crystal structures and a semiconductor film layer (also referred to as a semiconductor thin film layer) stacked in that order, and holes are formed among the multiple seed crystal structures and communicated with one another;

lifting-off the multiple seed crystal structures and the semiconductor film layer from the first substrate layer; and

bonding a side of the multiple seed crystal structures facing away from the semiconductor film layer with a second substrate layer to complete a process of lifting-off the semiconductor film and transferring the substrate.

In one embodiment of the disclosure, the preparing a semiconductor film-substrate structure includes:

selecting the first substrate layer;

preparing the multiple seed crystal structures on the first substrate layer; and

growing the semiconductor film layer on the multiple seed crystal structures.

In one embodiment of the disclosure, the preparing the multiple seed crystal structures on the first substrate layer includes:

forming multiple convex structures and multiple concave structures on a surface of the first substrate layer;

growing an epitaxial layer with a smooth surface on a side of the first substrate layer having the multiple convex structures; and

removing the epitaxial layer above each of the multiple concave structures on the first substrate layer until the first substrate layer being exposed, while retaining at least a part of the epitaxial layer above each of the multiple convex structures on the first substrate layer, to thereby form the multiple seed crystal structures.

In one embodiment of the disclosure, the forming multiple convex structures and multiple concave structures on a surface of the first substrate layer includes:

growing a mask layer on the first substrate layer;

performing exposure, development and etching onto the mask layer as per a preset pattern, to expose a part of the surface of the first substrate layer;

etching the exposed part of the surface of the first substrate layer to form the multiple convex structures and the multiple concave structures on the surface of the first substrate layer after the etching.

In one embodiment of the disclosure, the lifting-off multiple seed crystal structures and the semiconductor film layer from the first substrate layer includes:

using a chemical etching method to lift-off the multiple seed crystal structures and the semiconductor film layer from the first substrate layer.

In one embodiment of the disclosure, the using a chemical etching method to lift-off the multiple seed crystal structures and the semiconductor film layer from the first substrate layer includes:

forming multiple first opening regions in the semiconductor film layer, where the multiple first opening regions are communicated with the holes;

disposing a support substrate onto the semiconductor film layer, where the support substrate is disposed with multiple second opening regions respectively communicated with the multiple first opening regions; and

injecting a corrosive liquid into the holes among the multiple seed crystal structures through the multiple first opening regions and the multiple second opening regions to thereby strip-off the multiple seed crystal structures and the semiconductor film layer from the first substrate layer.

In one embodiment of the disclosure, before the strip-off the multiple seed crystal structures and the semiconductor film layer from the first substrate layer further includes:

growing a first functional layer on the semiconductor film layer, where the first functional layer is disposed with multiple fourth opening regions, the multiple fourth opening regions are respectively communicated with the multiple first opening regions.

In one embodiment of the disclosure, the using a chemical etching method to lift-off the multiple seed crystal structures and the semiconductor film layer from the first substrate layer includes:

adhering a support substrate to the semiconductor film layer;

etching multiple third opening regions on a side of the first substrate layer facing away from the multiple seed crystal structures, where the multiple third opening regions are respectively communicated with the holes; and

injecting a corrosive liquid into the holes among the multiple seed crystal structures through the multiple third opening regions to thereby lift-off the multiple seed crystal structures and the semiconductor film layer from the first substrate layer.

In one embodiment of the disclosure, before the lifting-off the multiple seed crystal structures and the semiconductor film layer from the first substrate layer, the method further includes: growing a second functional layer on the semiconductor film layer.

In one embodiment of the disclosure, the bonding a side of the multiple seed crystal structures facing away from the semiconductor film layer with a second substrate layer to complete a process of lifting-off the semiconductor film and transferring the substrate includes:

adhering the side of the multiple seed crystal structures facing away from the semiconductor film layer to the second substrate layer; and

removing the support substrate by using an immersion method.

Embodiments of the disclosure mainly can achieve beneficial effects as follows.

Aiming at the problem of semiconductor film lifting-off and substrate transfer of GaN material series, the disclosure proposes a new method for film lifting-off and substrate transfer. The method can be compatible with various epitaxial substrate materials. Moreover, the smooth surface of epitaxial layer film (semiconductor film layer) of the device can be retained, which does not affect the subsequent processing process of growing other functional layers for preparing the device on the epitaxial layer film, and the first substrate layer with poor thermal conductivity can be replaced with the second substrate layer with excellent thermal conductivity. In addition, the second substrate layer can be a conductive substrate or an insulating substrate, which further expands the application space of the device.

The disclosure will be further described in detail below in conjunction with accompanying drawings and embodiments.

### BRIEF DESCRIPTION OF THE DRAWINGS

FIG. 1 is a flowchart of a method for semiconductor film lift-off and substrate transfer according to an embodiment of the disclosure.

FIGS. 2a-2l are schematic diagrams of a method for semiconductor film lift-off and substrate transfer according to an embodiment of the disclosure.

FIGS. 3a-3d are schematic structural diagrams of a first substrate layer with graphical forms according to an embodiment of the disclosure.

FIGS. 4a-4e are schematic diagrams of another method for semiconductor film lift-off and substrate transfer according to an embodiment of the disclosure.

FIGS. 5a-5f are schematic diagrams of further another method for semiconductor film lift-off and substrate transfer according to an embodiment of the disclosure.

FIGS. 6a-6f are schematic diagrams of still another method for semiconductor film lift-off and substrate transfer according to an embodiment of the disclosure.

### DETAILED DESCRIPTION OF EMBODIMENTS

The disclosure will be further described in detail in combination with specific embodiments, but embodiments of the disclosure are not limited to these.

### First Embodiment

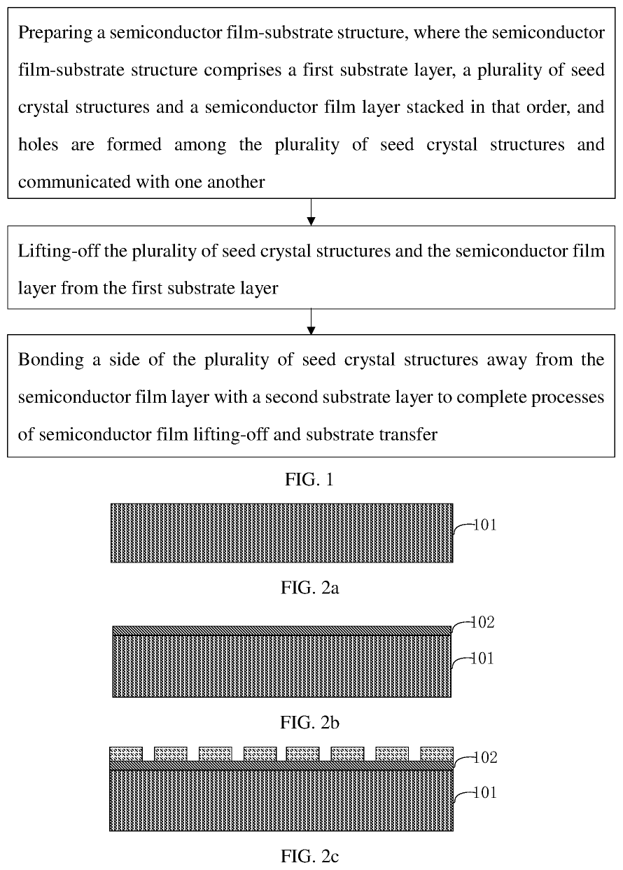

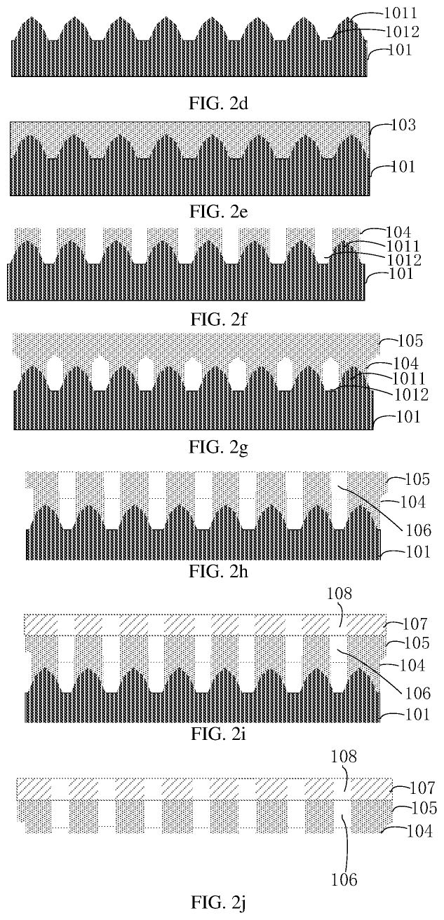

Referring to FIG. 1 and FIGS. 2a-2l, FIG. 1 is a flowchart of a method for semiconductor film lift-off and substrate transfer provided by the embodiment of the disclosure, and FIGS. 2a-2l are schematic diagram of a method for semiconductor film lift-off and substrate transfer provided by the embodiment of the disclosure. The illustrated embodiment provides a method for semiconductor film lift-off and substrate transfer, and including step 1.1 through step 1.3 as follow.

Step 1.1, preparing a semiconductor film-substrate structure, where the semiconductor film-substrate structure includes a first substrate layer, multiple seed crystal structures and a semiconductor film layer stacked in that order, and holes are formed among the multiple seed crystal structures and communicated with one another.

Step 1.11, with reference to FIG. 2a, selecting the first substrate layer 101.

Specifically, the first substrate layer 101 may include, for example, silicon (Si), silicon carbide (SiC), diamond, sapphire (Al₂O₃), gallium arsenide (GaAs), aluminum nitride (AlN), gallium nitride (GaN), metal, metal oxide, compound semiconductor, glass, quartz, composite material, etc. Alternatively, the first substrate layer 101 may include a single crystal material with a specific crystal phase orientation, such as m-plane SiC or sapphire α-plane sapphire, y-plane sapphire, C-plane sapphire. The first substrate layer 101 may include a material composed of a free non-doped, n-type or p-type doped material.

Step 1.12, preparing the multiple seed crystal structures 104 on the first substrate layer 101. Specifically, the multiple seed crystal structures 104 on the first substrate layer 101 are mutually independent structures, and there are holes among the seed crystal structures, and these holes are communicated with one another. The materials of these seed crystal structures can be, for example, III-V compound semiconductor materials, specifically GaN material series.

In the illustrated embodiment, the multiple seed crystal structures 104 can be prepared on the first substrate layer 101 through steps 1.121 to 1.123 as follow.

Step 1.121, forming multiple convex structures 1011 and multiple concave structures 1012 on a surface of the first substrate layer 101.

Specifically, in the illustrated embodiment, the multiple convex structures 1011 and the multiple concave structures 1012 are formed on the surface of the first substrate layer 101 in a graphical manner. The multiple convex structures 1011 and the multiple concave structures 1012 can be distributed in a periodic manner or in a non-periodic manner. In order to simplify and facilitate manufacturing process, it is preferred that the multiple convex structures 1011 and the multiple concave structures 1012 are distributed in a periodic manner, and the periodic distribution can be completely periodic uniform distribution and/or local unit uniform distribution.

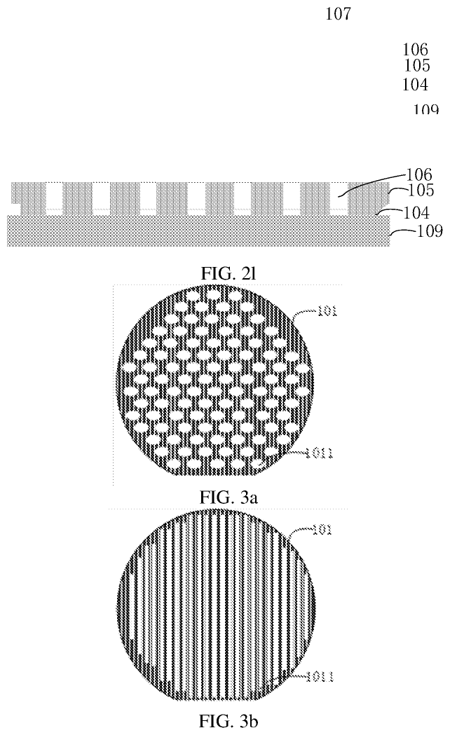

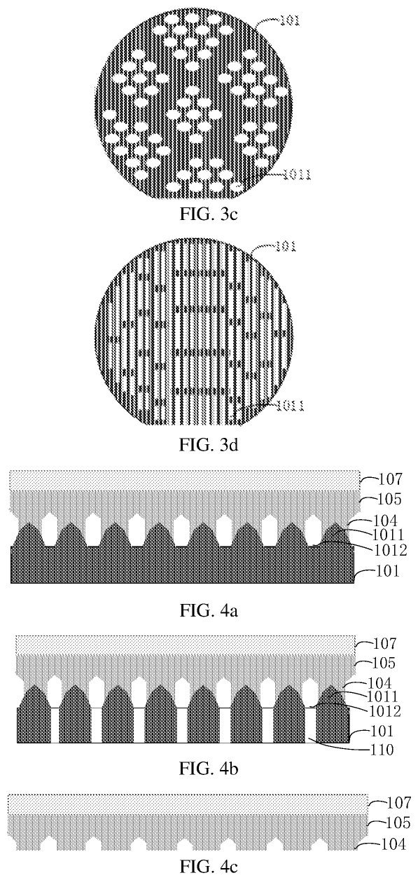

In an embodiment, with reference to FIGS. 3a-3d, a longitudinal profile of each of the multiple convex structures 1011 obtained in this embodiment can be one or a combination selected from a group consisting of triangular, square, circular, elliptical and trapezoidal, and the longitudinal profile of each of the multiple convex structures 1011 can also be other shapes, which is not specifically limited in this embodiment.

In an embodiment, a top of each of the multiple convex structures 1011 does not have any platform area, that is, a top contour line of at least one profile in the longitudinal profile of each of the multiple convex structures 1011 is not a straight line parallel to a horizontal plane.

Specifically, the forming multiple convex structures 1011 and multiple concave structures 1012 on the first substrate layer 101 may include steps 1.1211 through 1.1213 as follow.

Step 1.1211, with reference to FIG. 2b, growing a mask layer 102 on the first substrate layer 101.

Specifically, the mask layer 102 is coated and/or deposited on the surface of the first substrate layer 101 with photoresist. When a coating process is used, the mask layer 102 may be, for example, a photoresist mask. When a deposition process is used, the mask layer 102 may be, for example, silicon dioxide (SiO₂) and/or trisilicon tetranitride (Si₃N₄), metal nitrides and/or metal oxides.

Step 1.1212, with reference to FIG. 2c, performing exposure, development and etching onto the mask layer 102 as per a preset pattern to expose a part of the surface of the first substrate layer 101.

Specifically, the preset pattern is a required pattern to be represented by the first substrate layer 101, and the required pattern can be transferred to the mask layer 102 through exposure, development and etching processes, so as to expose the part of the surface of the first substrate layer 101.

Step 1.1213, with reference to FIG. 2d, etching the exposed part of the surface of the first substrate layer 101 to form the multiple convex structures 1011 and the multiple concave structures 1012 on the surface of the first substrate layer 101.

Alternatively, the multiple convex structures 1011 and the multiple concave structures 1012 may be formed on the first substrate layer 101 in other ways. For example, the multiple convex structures 1011 and the multiple concave structures 1012 may be formed on the first substrate layer 101 by using a deposition mask layer and an etching method according to a preset period and a preset pattern.

Specifically, a layer of insulating material (i.e., mask layer) can be deposited on the surface of the first substrate layer 101, which can be one of Al₂O₃, SiO₂, Si₃N₄ and photoresist or a combination thereof, forming an arrangement pattern of periodic distribution (or non-periodic distribution) by etching, and adjusting its contour shape to form the convex structures 1011 with required shapes by redeposition and re-etching. The deposition process can adopt mechanical coating, chemical vapor deposition method or physical vapor deposition method, and the deposition material can be one or a combination selected from a group consisting of Al₂O₃, SiO₂, Si₃N₄ and photoresist.

In this embodiment, the mask layer can be removed or not. At this time, the GaN material series retained below the mask layer are high-quality seed crystal structures obtained by lateral growth above the multiple convex structures of the first substrate layer.

Step 1.122, with reference to FIG. 2e, growing an epitaxial layer 103 with a smooth surface on a side of the first substrate layer 101 with the multiple convex structures 1011.

Specifically, in this embodiment, epitaxial layer material begins to grow on one side of the first substrate layer 101 with the multiple convex structure 1011. The epitaxial layer material first starts to grow on the surface of the first substrate layer 101 with the multiple concave structures 1012 until the epitaxial layer material completely covers the multiple convex structures 1011 on the first substrate layer 101 to form the epitaxial layer 103 with a smooth surface.

In an embodiment, the epitaxial growth can be performed on one side of the first substrate layer 101 with the multiple convex structures 1011 by using chemical vapor deposition method or the hydride vapor phase epitaxial growth method to obtain the epitaxial layer 103 with a smooth surface. In this embodiment, process parameters of the epitaxial layer 103 are not specifically limited, and the requirement can be satisfied as long as the epitaxial layer 103 with a smooth surface can be grown on one side of the first substrate layer 101 with the multiple convex structures 1011. It should be understood that those skilled in the art can carry out the epitaxial growth by controlling the process conditions of the epitaxial layer 103 and selecting the appropriate graphic shape and size of each of the multiple convex structures 1011 and the multiple concave structures 1012.

In the embodiment, the chemical vapor deposition method may include, for example, metal-organic chemical vapor deposition (MOCVD) or reduced pressure chemical vapor deposition (RPCVD).

In the embodiment, the material of the epitaxial layer 103 may be III-V compound semiconductor material, for example, GaN material series.

In an embodiment, GaN material series may include, for example, GaN, BN, aluminium gallium indium nitride (AlₓGa_{y}In_{1-x-y}N) (0≤x≤1, 0≤y≤1, 0≤x+y≤1) alloy materials, Indium boride (InP), gallium arsenide (GaAs), aluminium gallium indium boride (AlₓGa_{y}In_{1-x-y}P) (0≤x≤1, 0≤y≤1, 0≤x+y≤1) alloy materials and aluminium gallium indium arsenide (AlₓGa_{y}In_{1-x-y}As) (0≤x≤1, 0≤y≤1, 0≤x+y≤1) alloy materials.

In an embodiment, the GaN material series can be at least one of a group consisting of undoped, n-type and p-type doped materials.

In an embodiment, the growth method of GaN material series can be deposited with doped materials only or undoped materials only, or with a combination of undoped and doped steps, or with a combination of n-doped and p-doped materials.

Step 1.123, with reference to FIG. 2f, removing the epitaxial layer 103 above each of the multiple concave structures 1012 on the first substrate layer 101 until the first substrate layer 101 is exposed, while retaining at least a part of the epitaxial layer 103 above each of the multiple convex structures 1011 on the first substrate layer 101, to thereby form the multiple seed crystal structures 104; and the multiple seed crystal structures 104 are the epitaxial layer material above the multiple convex structures 1011.

Specifically, in this embodiment, the corresponding epitaxial layer 103 above each of the multiple concave structures 1012 is removed until the surface of the first substrate layer 101 is completely exposed, and it is necessary to ensure that there is no residue of epitaxial layer material on the exposed surface of the first substrate layer 101, while retaining the corresponding epitaxial layer 103 above each of the multiple convex structures 1011. The epitaxial layer 103 reserved above each of the multiple convex structures 1011 is regarded as one seed crystal structure 104, and each of the multiple seed crystal structures 104 formed above each of the multiple convex structures 1011 exists independently, that is, all seed crystal structures 104 exist above the multiple convex structures 1011 independently of each other. In this embodiment. In this embodiment, the portion of the epitaxial layer 103 above the multiple convex structures 1011 encloses both a top area of each of the multiple convex structures 1011 and a side area of each of the multiple convex structures 1011. The size of the side area can be selected according to an actual demand, which is not specifically limited in this embodiment. In this embodiment, because the corresponding epitaxial layer 103 above the concave structure 1012 is a heterogeneous material with the first substrate layer 101, there is a problems that lattice mismatch and thermal mismatch have a large impact and more defects. Therefore, this embodiment removes the corresponding epitaxial layer 103 above the exposed concave structures 1012.

The size of the plane area of each of the multiple seed crystal structures is in a range of 0.01 square microns to 300000 square microns, preferably 1 square micron to 100 square microns, more preferably 1 square micron to 30 square microns.

This embodiment proposes a new method for preparing patterned substrate. Although the patterned substrate proposed in this embodiment is based on heterogeneous substrate material, the pattern surface of the patterned substrate is no longer heterogeneous substrate material, but transformed into a seed crystal structure with isolated island distribution. Moreover, the spacing regions between the seed crystal structures of the patterned substrate are depressions of heterogeneous substrate materials with a certain depth and width, these seed crystal structures are the seed crystal structures of GaN material series with high crystal quality obtained by epitaxial lateral over-growth (ELOG), and high quality material films and devices can be obtained by subsequent material growth based on the patterned substrates formed by these seed crystal structures.

Step 1.13, with reference to FIG. 2g, growing a semiconductor film layer 105 on the multiple seed crystal structures 104.

Specifically, the semiconductor film layer material continues to be grown on the multiple seed crystal structures 104 by the chemical vapor deposition method (such as MOCVD, RPCVD, etc.), vapor phase epitaxial growth (such as metal-organic compound vapor epitaxy (MOVPE), hydride vapor phase epitaxy (HYPE)), or molecular beam epitaxy (MBE), until the semiconductor film layer 105 with a smooth surface is obtained. In an embodiment, the semiconductor thin film layer 105 is made of the same material as the multiple seed crystal structures 104, for example, both are GaN material series. The semiconductor film layer 105 is grown on the multiple seed crystal structures 104. Due to a large number of holes (i.e. concave structures 1012) among the multiple seed crystal structures 104 and the first substrate layer 101, the semiconductor film layer 105 can be almost unaffected by the lattice mismatch and thermal mismatch of the first substrate layer 101 made of heterogeneous materials, and has the similar characteristics to the materials grown on the homogeneous crystal substrate, and can be used to subsequently continue growing functional layers of devices, which provides a high-quality first epitaxial layer base for the functional layers required by these device structures.

In the embodiment, the material of the semiconductor film layer 105 may be a group III-V compound semiconductor material, for example, GaN material series. In an embodiment, the GaN material series may include, for example, GaN, BN, AlₓGa_{y}In_{1-x-y}N (0≤x≤1, 0≤y≤1, 0≤x+y≤1) alloy materials, InP, GaAs, AlₓGa_{y}In_{1-x-y}P (0≤x≤1, 0≤y≤1, 0≤x+y≤1) alloy materials and AlₓGa_{y}In_{1-x-y}As (0≤x≤1, 0≤y≤1, 0≤x+y≤1) alloy materials.

In an embodiment, the semiconductor film layer 105 is made of the same material as the multiple seed crystal structures 104.

Since the pattern surface of the patterned substrate prepared by the preparation method of the first embodiment is transformed into the multiple seed crystal structures of GaN material series with mutually isolated island distribution, a first single crystal film layer formed by the closure of these seed crystal structures by the ELOG process has high quality. In an embodiment, since the spacing region among the seed crystal structures of the patterned substrate is formed on the first substrate layer and has a certain depth and width, the multiple concave structures of the heterogeneous substrate layer (i.e., first substrate layer) will not grow GaN material series when preparing the semiconductor film layer, the process of closure the seed crystal structures by the epitaxial lateral over-growth is completed above the multiple concave structures of the heterogeneous substrate layer. Therefore, a large number of interconnected holes will be formed between and the heterogeneous substrate layer and the semiconductor film layer with smooth surface obtained by the epitaxial lateral over-growth between the multiple seed crystal structures. Due to the existence of these holes, it can not only greatly reduce the defect problem of semiconductor film layer caused by lattice mismatch and thermal mismatch between heterogeneous substrate layer and GaN material series, so as to improve the crystallization quality of semiconductor film layer, but also provide favorable conditions for lifting-off semiconductor film layer from heterogeneous substrate layer.

Step 1.2, lifting-off the multiple seed crystal structures 104 and the semiconductor film layer 105 from the first substrate layer 101.

In this embodiment, the multiple seed crystal structures 104 and the semiconductor film layer 105 can be lifted-off from the first substrate layer by chemical etching. By lifting-off the multiple seed crystal structures 104 and the semiconductor film layer 105 from the first substrate layer, the problem of poor thermal conductivity caused by the heterogeneous substrate layer can be removed.

Specifically, the step of lifting-off the multiple seed crystal structures 104 and the semiconductor film layer 105 from the first substrate layer 101 can be realized by steps 1.21 through 1.23 as follow.

Step 1.21, with reference to FIG. 2h, forming multiple first opening regions 106 in the semiconductor film layer 105, where the multiple first opening regions 106 are respectively communicated with the holes (i.e. positions of the multiple concave structures 1012).

Specifically, there are multiple interconnected holes between the formed smooth semiconductor film layer 105 and the first substrate layer 101, the multiple first opening regions 106 are formed in the semiconductor film layer 105, and the multiple interconnected holes can be respectively communicated with the outside through the multiple first opening regions 106. It should be understood that this embodiment does not make specific requirements for shapes, positions and quantity of the first opening regions 106, as long as they can be communicated with the holes.

In an embodiment, the multiple first opening regions 106 may be opening regions naturally formed by controlling spacings of seed crystal structure distribution in combination with the growth process, opening regions obtained by dry etching or wet etching, or opening regions obtained by solvent immersion dissolution. The multiple first opening regions 106 may be on the smooth surface of the semiconductor film layer 105, on the edge of the semiconductor film layer 105, or on both the smooth surface and the edge of the semiconductor film layer 105.

Step 1.22, with reference to FIG. 2i, adhering a support substrate 107 to the semiconductor film layer 105, where the support substrate 107 is disposed with multiple second opening regions 108 respectively communicated with the multiple first opening regions 106.

Specifically, the support substrate 107 is adhered to the semiconductor film layer 105 through an adhesive, and air bubbles in the adhesive are removed in a vacuum environment, while the multiple second opening regions 108 of the support substrate 107 are respectively communicated with the multiple first opening regions 106. It should be understood that this embodiment does not make specific requirements for shapes, positions and quantity of the second opening regions 108, as long as they can be communicated with the holes. Moreover, the multiple second opening regions 108 can be a structure formed during processing the support substrate 107, thereby exposing the multiple first opening regions 106, or they can be opening regions etched on a side of the support substrate 107 facing away from the semiconductor film layer 105 by dry etching and/or wet etching after adhering the support substrate 107 to the semiconductor film layer 105, such that the multiple interconnected holes between the semiconductor film layer 105 and the first substrate layer 101 can be communicated with outside world through the multiple second open regions 108.

In an embodiment, material of the support substrate 107 may be one or a combination selected from a group consisting of copper (Cu), aluminum nitride (AlN), glass, silicon (Si), silicon carbide (SiC), metal, metal nitride, metal oxide, zinc oxide (ZnO), plastic and polymer compound.

In an embodiment, the adhesive may be one or a combination selected from a group consisting of organic resin, silica gel, glass adhesive and polymer adhesive.

Step 1.23, with reference to FIG. 2j, injecting a corrosive liquid (also referred to as a chemical corrosive liquid) into the holes among the multiple seed crystal structures 104 through the multiple first opening regions 106 and the multiple second opening regions 108 to thereby lift-off the multiple seed crystal structures 104 and the semiconductor film layer 105 from the first substrate layer 101.

Specifically, the chemical corrosive liquid is injected into the holes among the multiple seed crystal structures 104 through the multiple first opening regions 106 and the multiple second opening regions 108, and the multiple seed crystal structures 104 and the semiconductor film layer 105 are lifted-off from the first substrate layer 101 by etching the semiconductor material connected between the multiple seed crystal structures 104 and the first substrate layer 101.

In an embodiment, the chemical corrosive liquid can be one or a combination selected from a group consisting of phosphoric acid, nitric acid, hydrogen peroxide, sulfuric acid, potassium hydroxide, sodium hydroxide, ammonia, acidic solution and alkaline solution. The corrosion process can be single corrosive liquid corrosion and/or multiple types of corrosive liquid corrosion alternately and/or periodically in a certain order.

In addition, in the process of lifting-off the multiple seed crystal structures 104 and the semiconductor film layer 105 from the first substrate layer 101, the first substrate layer 101 may be heated, the support substrate 107 may be heated, or the first substrate layer 101 and the support substrate 107 may be heated at the same time.

Step 1.3, bonding a side of the multiple seed crystal structures 104 facing away from the semiconductor film layer 105 with a second substrate layer 109.

In this embodiment, the semiconductor film layer 105 and the multiple seed crystal structures 104 lifted-off by chemical etching are bonded with the second substrate layer 109 to form a semiconductor device having both the support substrate 107 and the second substrate layer 109.

In an embodiment, material of the second substrate layer 109 may be one or a combination selected from a group consisting of Cu, AlN, glass, Si, SiC, metal, metal nitride, metal oxide, ZnO, plastic and polymer compound.

Specifically, the step 1.3 can be realized through steps 1.31 through 1.32 as follow.

Step 1.31, with reference to FIG. 2k, adhering the side of the multiple seed crystal structures 104 facing away from the semiconductor film layer 105 to the second substrate layer 109.

In this embodiment, the multiple seed crystal structures 104 are bonded with the second substrate layer 109, preferably forming a layer of metal on connecting surfaces between the multiple seed crystal structure 104 and the second substrate layer 109 by evaporation or sputtering, and then electroplating a layer of metal on the second substrate layer material as the second substrate layer 109. Alternatively, another substrate may be bonded on the metal surface to form a composite second substrate layer 109, or the second substrate layer 109 may be directly bonded on the multiple seed crystal structures 104 of the connecting surfaces.

Step 1.32, with reference to FIG. 2l, removing the support substrate 107 from the semiconductor film layer 105 by an immersion method to complete a process of the semiconductor film lifting-off and the substrate transfer.

Specifically, the semiconductor film layer 105 having both the support substrate 107 and the second substrate layer 109 is soaked in a solvent to dissolve the adhesive, remove the support substrate 107 to restore the smooth semiconductor film layer 105, thereby obtaining a semiconductor film with the second substrate layer 109 after semiconductor film lifting-off and substrate transfer. The process of removing the support substrate 107 may be to heat the second substrate layer 109, heat the support substrate 107, or heat the second substrate layer 109 and the support substrate 107 at the same time.

In actual use, the part of the semiconductor film layer with open regions can be removed, and the rest without open regions can be reserved for further preparation or use of the required device.

In an embodiment, the solvent can be one or a combination selected from a group consisting of organic solvent, phosphoric acid, nitric acid, hydrogen peroxide, sulfuric acid, potassium hydroxide, sodium hydroxide, ammonia, acidic solution and alkaline solution. The process of dissolving can be single solvent and/or multiple types of solvents carried out alternately and/or periodically in a certain order.

Aiming at the problem of semiconductor film lifting-off and substrate transfer of the GaN material series, the disclosure proposes a new method of film lifting-off and substrate transfer. The method can be compatible with various epitaxial substrate materials, while retaining the smooth surface of the semiconductor film layer without affecting the subsequent processing process of growing other functional layers used to prepare devices on semiconductor film layer, and the first substrate layer with poor thermal conductivity can be replaced with the second substrate layer with excellent thermal conductivity. Further, the second substrate layer can be a conductive substrate or an insulating substrate, which further expands the application space of the device. In addition, the lifting-off process of the semiconductor film layer does not generate a lot of heat, so it will not cause any damage to the device. Therefore, the first substrate layer with poor thermal conductivity can be directly replaced by the second substrate layer with good thermal conductivity after the film lifting-off and substrate transfer of the GaN material series semiconductor device, so that the semiconductor device prepared by this method have good heat dissipation capacity and are more suitable for various high-power application scenarios. In addition, since the method of the embodiment can generate a large number of holes between the second substrate layer and the semiconductor film layer of the GaN material series, which is conducive to reducing the defect density of the semiconductor film layer of the GaN material series and improving the crystal quality of the semiconductor film layer of the GaN material series, the method can also further improve the performance of the semiconductor device of the GaN material series.

### Second Embodiment

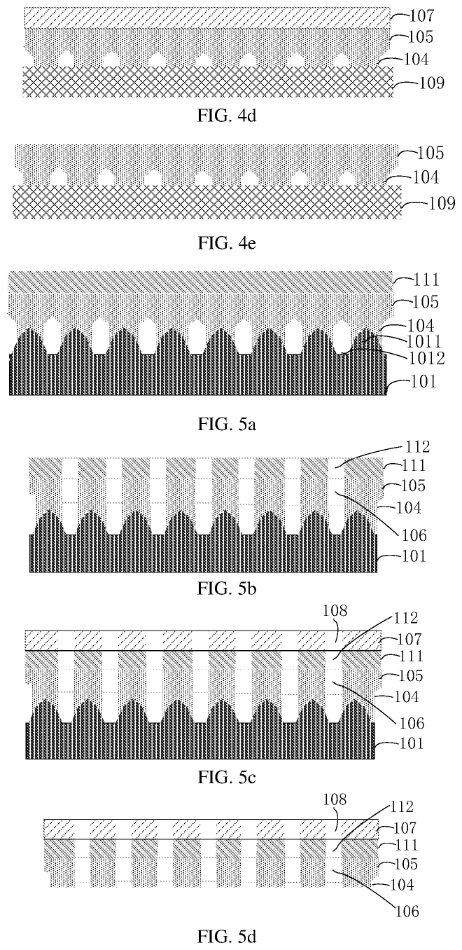

On the basis of the first embodiment, the disclosure also proposes a method for lifting-off the first substrate layer. The semiconductor film-substrate structure is obtained through the step 1.1 in first embodiment, and then the multiple seed crystal structures and semiconductor film layer are lifted-off from the first substrate layer by using the lifting-off method provided in this embodiment. Referring to FIGS. 4a-4e, FIGS. 4a-4e are schematic diagrams of a method for semiconductor film lift-off and substrate transfer provided by this embodiment of the disclosure. Specifically, the lifting-off method provided by this embodiment may include:

step 2.1, lifting-off the multiple seed crystal structures 104 and the semiconductor film layer 105 from the first substrate layer 101.

In this embodiment, the multiple seed crystal structures 104 and the semiconductor film layer 105 can be lifted-off from the first substrate layer 101 by chemical etching. By lifting-off the multiple seed crystal structures 104 and the semiconductor film layer 105 from the first substrate layer, the problem of poor thermal conductivity caused by heterogeneous substrate layer can be solved.

Specifically, the step of the lifting-off the multiple seed crystal structures 104 and the semiconductor film layer 105 from the first substrate layer 101 can be realized by steps 2.11 through 2.13 as follow.

Step 2.11, with reference to FIG. 4a, adhering the support substrate 107 to the semiconductor film layer 105.

Specifically, the semiconductor film layer 105 is adhered to the support substrate 107 by an adhesive, and air bubbles in the adhesive are removed in a vacuum environment.

In an embodiment, material of the support substrate 107 may be one or a combination selected from a group consisting of Cu, AlN, glass, Si, SiC, metal, metal nitride, metal oxide, ZnO, plastic and polymer compound.

In an embodiment, the adhesive may be one or a combination selected from a group consisting of organic resin, silica gel, glass adhesive and polymer adhesive.

Step 2.12, with reference to FIG. 4b, etching multiple third opening regions on a side of the first substrate layer 101 facing away from the multiple seed crystal structures 104, where the multiple third opening regions are communicated with the holes.

Specifically, there are multiple interconnected holes between the formed smooth semiconductor film layer 105 and the first substrate layer 101, the multiple third opening regions 110 are formed on the first substrate layer 10, the multiple interconnected holes can be communicated with outside through the multiple third opening regions 110, and the multiple third opening regions 110 can be etched by dry etching and/or wet etching on one side of the first substrate layer 101 facing away from the semiconductor film layer 105, so that the multiple interconnected holes between the semiconductor film layer 105 and the first substrate layer 101 can be communicated with the outside through the multiple third opening regions 110. It should be understood that this embodiment does not make specific requirements for shapes, positions and quantity of the third opening regions 110, as long as they can be communicated with the holes.

Step 2.13, with reference to FIG. 4c, injecting a corrosive liquid (also referred to as a chemical corrosive liquid) into the holes among the multiple seed crystal structures 104 through the multiple third opening regions 110, so that the multiple seed crystal structures 104 and the semiconductor film layer 105 are lifted-off from the first substrate layer 101.

Specifically, the chemical corrosive liquid is injected into the holes among the multiple seed crystal structures 104 through the multiple third opening regions 110, and the multiple seed crystal structures 104 and the semiconductor film layer 105 are lifted-off from the first substrate layer 101 by etching the semiconductor material connected between the multiple seed crystal structures 104 and the first substrate layer 101.

In an embodiment, the chemical corrosive liquid can be one or a combination selected from a group consisting of phosphoric acid, nitric acid, hydrogen peroxide, sulfuric acid, potassium hydroxide, sodium hydroxide, ammonia, acidic solution and alkaline solution. The corrosion process can be single corrosive liquid corrosion and/or multiple types of corrosive liquid corrosion alternately and/or periodically in a certain order.

Step 2.2, bonding a side of the multiple seed crystal structures 104 facing away from the semiconductor film layer 105 with a second substrate layer 109.

In the embodiment, the semiconductor film layer 105 and the multiple seed crystal structures 104 lifted-off by chemical etching are bonded with the second substrate layer 109 to form a semiconductor device having both the support substrate 107 and the second substrate layer 109.

In an embodiment, material of the second substrate layer 109 may be one or a combination selected from a group consisting of Cu, AlN, glass, Si, SiC, metal, metal nitride, metal oxide, ZnO, plastic and polymer compound.

Specifically, the step 2.2 can be realized through steps 2.21 through 2.22 as follow.

Step 2.21, with reference to FIG. 4d, adhering the side of the multiple seed crystal structures 104 facing away from the semiconductor film layer 105 to the second substrate layer 109.

In this embodiment, the multiple seed crystal structures 104 are bonded with the second substrate layer 109, preferably by forming a layer of metal on connecting surfaces between the multiple seed crystal structures 104 and the second substrate layer 109 by evaporation or sputtering, and then electroplating a layer of metal on the second substrate layer material as the second substrate layer 109. Alternatively, another substrate may be bonded on the metal surface to form a composite second substrate layer 109, or the second substrate layer 109 may be directly bonded on the multiple seed crystal structures 104 of the connecting surfaces.

Step 2.22, with reference to FIG. 4e, removing the support substrate 107 from the semiconductor film layer 105 by an immersion method to complete a process of the semiconductor film lifting-off and the substrate transfer.

Specifically, the semiconductor film layer 105 having both the support substrate 107 and the second substrate layer 109 is soaked in a solvent to dissolve the adhesive, remove the support substrate 107 to restore the smooth semiconductor film layer 105, thereby obtaining a semiconductor film with the second substrate layer 109 after semiconductor film lifting-off and substrate transfer. The process of removing the support substrate 107 may be to heat the second substrate layer 109, heat the support substrate 107, or heat the second substrate layer 109 and the support substrate 107 at the same time.

In an embodiment, the solvent can be one or a combination selected from a group consisting of organic solvent, phosphoric acid, nitric acid, hydrogen peroxide, sulfuric acid, potassium hydroxide, sodium hydroxide, ammonia, acidic solution and alkaline solution. The process of dissolving can be a single solvent and/or multiple types of solvents carried out alternately and/or periodically in a certain order.

In actual use, the part of the semiconductor film layer with open regions can be removed, and the rest without open regions can be reserved for further preparation or use of the required device.

The disclosure innovatively proposes that the technical advantages of the patterned substrate and the epitaxial lateral over-growth (ELOG) are compatible, and the first substrate layer with poor thermal conductivity can be finally replaced with the second substrate layer with excellent thermal conductivity through the multiple interconnected holes between the semiconductor film layer and the first substrate layer. Moreover, the smooth surface of the semiconductor film layer is retained, which does not affect the subsequent process processing of semiconductor film layer and can be compatible with various epitaxial substrate materials. For the semiconductor device manufactured by the method of this embodiment, the semiconductor film layer lifting-off process of the whole device does not generate a lot of heat, so it will not cause any damage to the device and improve the yield rate and reliability of the device. Furthermore, the semiconductor device prepared by the method of this embodiment has good heat dissipation capacity and is more suitable for various high-power application scenarios. In addition, the second substrate layer can be a conductive substrate or an insulating substrate, which can further expand the application space of the device and has great commercial value. The semiconductor film layer of the GaN material series obtained by this embodiment can basically get rid of the influence caused by the lattice mismatch and thermal mismatch of the substrate, and minimize the defect influence and stress influence. Therefore, the quality of the semiconductor film layer of the GaN material series can be close to that of the material prepared on the homogeneous single crystal substrate, the cost of research and application of semiconductor materials based on GaN material series can be greatly reduced, and this derivative application also has great research, application value and commercial value.

### Third Embodiment

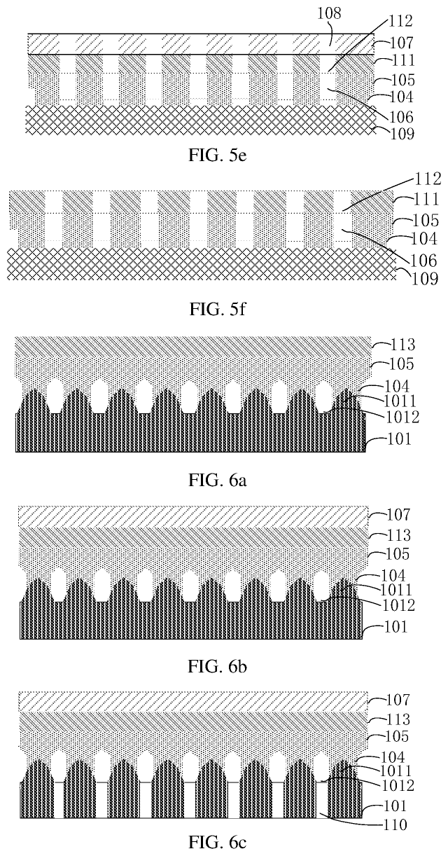

On the basis of the first embodiment, the disclosure also provides a method for semiconductor film lift-off and substrate transfer based on a device. The semiconductor film-substrate structure is obtained through step 1.1 in the first embodiment, and then a functional layer is grown on the semiconductor film layer of the semiconductor film-substrate structure obtained in the first embodiment. Referring to FIGS. 5a-5f, FIGS. 5a-5f are schematic diagrams of a method for semiconductor film lift-off and substrate transfer provided by this embodiment of the disclosure. Specifically, a method of growing a functional layer on the semiconductor film layer includes:

step 3.1, with reference to FIG. 5a, growing a first functional layer 111 on the semiconductor film layer 105, where the first functional layer 111 is disposed with multiple fourth opening regions, and the fourth opening region is communicated with the multiple first opening regions.

In the embodiment, the first functional layer 111 may be at least one selected from a group consisting of a n-type doped semiconductor material layer, a p-type doped semiconductor material layer, an unintentionally doped semiconductor material layer, a superlattice layer and a quantum well layer required for forming a photoelectric device and/or a power device, that is, the first functional layer 111 may be any one selected from a group consisting of the n-type doped semiconductor material layer, the p-type doped semiconductor material layer, the unintentionally doped semiconductor material layer, the superlattice layer and the quantum well layer, and can also be a combination of multiple structures of the n-type doped semiconductor material layer, the p-type doped semiconductor material layer, the unintentionally doped semiconductor material layer, the superlattice layer and the quantum well layer. It's illustrated by the combination of multiple structures, for example, the n-type doped semiconductor material layer, the p-type doped semiconductor material layer, the unintentionally doped semiconductor material layer, the superlattice layer and the quantum well layer are sequentially grown on the semiconductor film layer 105 to form a photoelectric device and/or a power device. For example, the n-type doped semiconductor material layer, the p-type doped semiconductor material layer, and the unintentionally doped semiconductor material layer are sequentially grown on the semiconductor film layer 105 to form a photoelectric devices and/or a power device. For example, the n-type doped semiconductor material layer, the p-type doped semiconductor material layer and the superlattice layer are sequentially grown on the semiconductor film layer 105 to form a photoelectric device and/or a power device. For a combination of multiple structures, this embodiment does not make specific requirements for growth sequence of the n-type doped semiconductor material layer, the p-type doped semiconductor material layer, the unintentionally doped semiconductor material layer, the superlattice layer and the quantum well layer on semiconductor film layer 105, which can be adjusted by those skilled in the art according to actual requirements and applications. In addition, the first functional layer 111 may also be other material layers forming the photoelectric device and/or the power device, which is not specifically limited in this embodiment. The growth process of the first functional layer 111 may be, for example, MOCVD or other common growth processes, which are not specifically limited in this embodiment.

Step 3.2, lifting-off the multiple seed crystal structures 104 and the semiconductor film layer 105 from the first substrate layer 101.

In this embodiment, the multiple seed crystal structures 104 and the semiconductor film layer 105 can be lifted-off from the first substrate layer 101 by chemical etching. By lifting-off the multiple seed crystal structures 104 and the semiconductor film layer 105 from the first substrate layer 101, the problem of poor thermal conductivity caused by a heterogeneous substrate layer can be solved.

Specifically, the step of lifting-off the multiple seed crystal structures 104 and the semiconductor film layer 105 from the first substrate layer 101 can be realized by steps 3.21 through 3.23 as follow.

Step 3.21, with reference to FIG. 5b, forming multiple fourth opening regions 112 on the first functional layer 111, where the multiple fourth opening regions 112 are respectively communicated with the multiple first opening regions 106.

Specifically, there are multiple interconnected holes between the formed smooth semiconductor film layer 105 and the first substrate layer 101, the multiple fourth opening regions 112 are formed on the first functional layer 111, and the interconnected holes can be communicated with outside through the multiple first opening regions 106 and the multiple fourth opening regions 112. It should be understood that this embodiment does not make specific requirements for shapes, positions and quantity of the fourth opening regions 112 There are no specific requirements for the position and quantity, as long as they can be communicated with the first opening regions 106.

In an embodiment, the multiple fourth opening regions 112 may be opening regions naturally formed by controlling spacings of seed crystal structure distribution in combination with the growth process, opening regions obtained by dry etching or wet etching, or opening regions obtained by solvent immersion dissolution. The multiple fourth opening regions 112 may be on a surface of the first functional layer 111, on an edge of the first functional layer 111, or on both the surface and the edge of the first functional layer 111.

Step 3.22, with reference to FIG. 5c, adhering the first functional layer 111 to the support substrate 107, where the support substrate 107 is disposed with multiple second opening region 108 respectively communicated with the multiple fourth opening regions 112.

Specifically, the first functional layer 111 is adhered to the support substrate 107 through an adhesive, and air bubbles in the adhesive are removed in a vacuum environment, while the multiple second opening regions 108 of the support substrate 107 are respectively communicated with the multiple fourth opening regions 112. It should be understood that this embodiment does not make specific requirements for shapes, positions and quantity of the second opening regions 108, as long as they can be communicated with the fourth opening regions 112. Moreover, the multiple second opening regions 108 can be a structure formed during processing the support substrate 107, thereby exposing the multiple first opening regions 106, or they can be opening regions etched on a side of the support substrate 107 facing away from the semiconductor film layer 105 by dry etching and/or wet etching after adhering the support substrate 107 to the first functional layer 111, such that the multiple interconnected holes among the semiconductor film layer 105 and the first substrate layer 101 can be communicated with the outside through the multiple second opening regions 108.

In an embodiment, material of the support substrate 107 may be one or a combination selected from a group consisting of Cu, AlN, glass, Si, SiC, metal, metal nitride, metal oxide, ZnO, plastic and polymer compound.

In an embodiment, the adhesive may be one or a combination selected from a group consisting of organic resin, silica gel, glass adhesive and polymer adhesive.

Step 3.23, with reference to FIG. 5d, injecting a corrosive liquid into the holes among the multiple seed crystal structures 104 through the multiple first opening regions 106, the multiple second opening regions 108 and the multiple fourth opening regions 112 to thereby lift-off the multiple seed crystal structures 104 and the semiconductor film layer 105 from the first substrate layer 101.

Specifically, the chemical corrosive liquid is injected into the holes among the multiple seed crystal structures 104 through the multiple first opening regions 106, the multiple second opening regions 108 and the multiple fourth opening regions 112, and the multiple seed crystal structures 104 and the semiconductor film layer 105 are lifted-off from the first substrate layer 101 by etching the semiconductor material connected between the multiple seed crystal structures 104 and the first substrate layer 101.

In an embodiment, the chemical corrosive liquid can be one or a combination selected from a group consisting of phosphoric acid, nitric acid, hydrogen peroxide, sulfuric acid, potassium hydroxide, sodium hydroxide, ammonia, acidic solution and alkaline solution. The corrosion process can be single corrosive liquid corrosion and/or multiple types of corrosive liquid corrosion alternately and/or periodically in a certain order.

In addition, in the process of lifting-off the multiple seed crystal structures 104 and the semiconductor film layer 105 from the first substrate layer 101, the first substrate layer 101 may be heated, the support substrate 107 may be heated, or the first substrate layer 101 and the support substrate 107 may be heated at the same time.

Step 3.3, bonding a side of the multiple seed crystal structures 104 facing away from the semiconductor film layer 105 with a second substrate layer 109.

In the embodiment, the semiconductor film layer 105 and the multiple seed crystal structures 104 lifted-off by chemical etching are bonded with the second substrate layer 109 to form a semiconductor device having both the support substrate 107 and the second substrate layer 109.

In an embodiment, material of the second substrate layer 109 may be one or a combination selected from a group consisting of Cu, AlN, glass, Si, SiC, metal, metal nitride, metal oxide, ZnO, plastic and polymer compound.

Specifically, the step 3.3 can be realized through steps 3.31 through 3.32 as follow.

Step 3.31, with reference to FIG. 5e, adhering the side of the multiple seed crystal structures 104 facing away from the semiconductor film layer 105 to the second substrate layer 109.

In this embodiment, the multiple seed crystal structures 104 are bonded with the second substrate layer 109, preferably by forming a layer of metal on connecting surfaces between the multiple seed crystal structures 104 and the second substrate layer 109 by evaporation or sputtering, and then electroplating a layer of metal on the second substrate layer material as the second substrate layer 109. Alternatively, another substrate may be bonded on the metal surface to form a composite second substrate layer 109, or the second substrate layer 109 may be directly bonded on the multiple seed crystal structures 104 of the connecting surfaces.

Step 3.32, with reference to FIG. 5f, removing the support substrate 107 from the semiconductor film layer 105 by using an immersion method to complete a process of the semiconductor film lifting-off and the substrate transfer.

The semiconductor film layer 105 having both the support substrate 107 and the second substrate layer 109 is soaked in a solvent to dissolve the adhesive, remove the support substrate 107 to restore the smooth semiconductor film layer 105, thereby obtaining a semiconductor film with the second substrate layer 109 after the semiconductor film lifting-off and substrate transfer. The process of removing the support substrate 107 may be to heat the second substrate layer 109, heat the support substrate 107, or heat the second substrate layer 109 and the support substrate 107 at the same time.

In an embodiment, the solvent can be one or a combination selected from a group consisting of organic solvent, phosphoric acid, nitric acid, hydrogen peroxide, sulfuric acid, potassium hydroxide, sodium hydroxide, ammonia, acidic solution and alkaline solution. The process of dissolving can be that single solvent and/or multiple types of solvents carried out alternately and/or periodically in a certain order.

In actual use, the parts of the semiconductor film layer and the functional layer with the opening regions can be removed, and the rest parts without the opening regions can be reserved for further preparation or use of the required device.

Aiming at the problem of semiconductor film lifting-off and substrate transfer of GaN material series, the disclosure proposes a new method of film lifting-off and substrate transfer. The method can be compatible with various epitaxial substrate materials. Moreover, the smooth surface of the semiconductor film layer of the device can be retained, which does not affect the subsequent processing process of growing other functional layer for preparing the device on the semiconductor film layer and the first substrate layer with poor thermal conductivity can be replaced with the second substrate layer with excellent thermal conductivity. Further, the second substrate layer can be a conductive substrate or an insulating substrate, which further expands the application space of the device. In addition, the lifting-off process of the semiconductor film layer does not generate a lot of heat, so it will not cause any damage to the device. Therefore, the first substrate layer with poor thermal conductivity can be directly replaced by the second substrate layer with good thermal conductivity after the film lifting-off and substrate transfer of the GaN material series semiconductor devices, so that the semiconductor devices prepared by this method have good heat dissipation capacity and are more suitable for various high-power application scenarios. In addition, since the method of the embodiment can generate a large number of holes among the second substrate layer and the semiconductor film layer of the GaN material series, which is conducive to reducing the defect density of the semiconductor film layer of the GaN material series and improving the crystal quality of the semiconductor film layer of the GaN material series, the method can also further improve the performance of the semiconductor device of the GaN material series.

### Fourth Embodiment

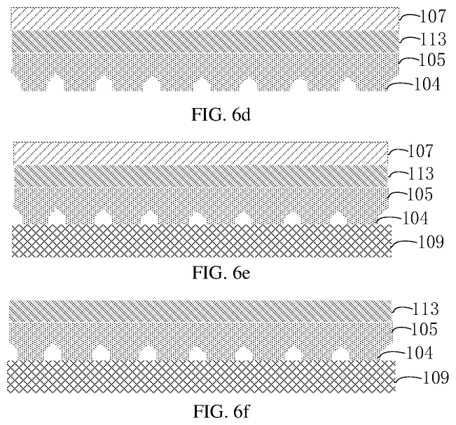

On the basis of the first embodiment, the disclosure also proposes a method for semiconductor film lift-off and substrate transfer to prepare device. The semiconductor film-substrate structure is obtained through the step 1.1 in the first embodiment, and then a functional layer is grown on the semiconductor film layer of the semiconductor film-substrate structure obtained in the first embodiment. Referring to FIGS. 6a-6f, FIGS. 6a-6f are schematic diagrams of a method for semiconductor film lift-off and substrate transfer provided by the embodiment of the disclosure. Specifically, a method of growing a functional layer on a semiconductor film layer includes:

step 4.1, with reference to FIG. 6a, growing a second functional layer 113 on the semiconductor film layer 105.

In this embodiment, the second functional layer 113 may be at least one selected from a group consisting of a n-type doped semiconductor material layer, a p-type doped semiconductor material layer, an unintentionally doped semiconductor material layer, a superlattice layer and a quantum well layer required for forming a photoelectric device and/or a power device, that is, the second functional layer 113 may be any one selected from a group consisting of the n-type doped semiconductor material layer, the p-type doped semiconductor material layer, the unintentionally doped semiconductor material layer, the superlattice layer and the quantum well layer, and can also be a combination of multiple structures of the n-type doped semiconductor material layer, the p-type doped semiconductor material layer, the unintentionally doped semiconductor material layer, the superlattice layer and the quantum well layer. It's illustrated by the combination of multiple structures. In addition, the second functional layer 113 may also be other material layers forming a photoelectric device and/or a power device, which is not specifically limited in the embodiment. The growth process of the second functional layer 113 may be, for example, MOCVD or other common growth processes, which are not specifically limited in this embodiment.

Step 4.2, lifting-off the multiple seed crystal structures 104 and the semiconductor film layer 105 from the first substrate layer 101.

In this embodiment, the multiple seed crystal structures 104 and the semiconductor film layer 105 can be lifted-off from the first substrate layer by chemical etching. By lifting-off the multiple seed crystal structures 104 and the semiconductor film layer 105 from the first substrate layer, the problem of poor thermal conductivity caused by a heterogeneous substrate layer can be solved.

Specifically, the step of the lifting-off the multiple seed crystal structures 104 and the semiconductor film layer 105 from the first substrate layer 101 can be realized by steps 4.21 through 4.23 as follow.

Step 4.21, with reference to FIG. 6b, adhering the second functional layer 113 to the support substrate 107.

Specifically, the second functional layer 113 is adhered to the support substrate 107 by an adhesive, and air bubbles in the adhesive are removed in a vacuum environment.

In an embodiment, material of the support the substrate 107 may be one or a combination selected from a group consisting of Cu, AlN, glass, Si, SiC, metal, metal nitride, metal oxide, ZnO, plastic and polymer compound.

In an embodiment, the adhesive may be one or a combination selected from a group consisting of organic resin, silica gel, glass adhesive and polymer adhesive.

Step 4.22, with reference to FIG. 6c, etching multiple third opening regions on a side of the first substrate layer 101 facing away from the multiple seed crystal structures 104, where the multiple third opening regions are communicated with the holes.

Specifically, there are multiple interconnected holes between the formed smooth semiconductor film layer 105 and the first substrate layer 101, and the multiple third opening regions 110 are formed on the first substrate layer 101, the multiple interconnected holes can be communicated with the outside through the multiple third opening regions 110, and the multiple third opening regions 110 can be etched by dry etching and/or wet etching on one side of the first substrate layer 101 facing away from the semiconductor film layer 105, so that the multiple interconnected holes between the semiconductor film layer 105 and the first substrate layer 101 can be communicated with the outside through the multiple third opening regions 110. It should be understood that this embodiment does not make specific requirements for shapes, positions and quantity of the third opening regions 110, as long as they can be communicated with the holes.

Step 4.23, with reference to FIG. 6d, injecting a corrosive liquid into the holes among the multiple seed crystal structures 104 through the multiple third opening regions 110 to lift-off the multiple seed crystal structures 104 and the semiconductor film layer 105 from the first substrate layer 101.

The corrosive liquid is injected into the holes among the multiple seed crystal structures 104 through the multiple third opening regions 110 to lift-off the multiple seed crystal structures 104 and the semiconductor film layer 105 from the first substrate layer 101.

Specifically, the chemical corrosive liquid is injected into the holes among the multiple seed crystal structures 104 through the multiple third opening regions 110, and the multiple seed crystal structures 104 and the semiconductor film layer 105 are lifted-off from the first substrate layer 101 by etching the semiconductor material connected between the multiple seed crystal structures 104 and the first substrate layer 101.

In an embodiment, the chemical corrosive liquid can be one or a combination selected from a group consisting of phosphoric acid, nitric acid, hydrogen peroxide, sulfuric acid, potassium hydroxide, sodium hydroxide, ammonia, acidic solution and alkaline solution. The corrosion process can be single corrosive liquid corrosion and/or multiple types of corrosive liquid corrosion alternately and/or periodically in a certain order.

Step 4.3, bonding a side of the multiple seed crystal structures 104 facing away from the semiconductor film layer 105 with a second substrate layer 109.

In the embodiment, the semiconductor film layer 105 and the multiple seed crystal structures 104 lifted-off by chemical etching are bonded with the second substrate layer 109 to form a semiconductor device having both the support substrate 107 and the second substrate layer 109.

In an embodiment, material of the second substrate layer 109 may be one or a combination selected from a group consisting of Cu, AlN, glass, Si, SiC, metal, metal nitride, metal oxide, ZnO, plastic and polymer compound.

Specifically, the step 4.3 can be realized through steps 4.31 through 4.32 as follow.

Step 4.31, with reference to FIG. 6e, adhering the side of the multiple seed crystal structures 104 facing away from the semiconductor film layer 105 to the second substrate layer 109.

In this embodiment, the multiple seed crystal structures 104 are bonded with the second substrate layer 109, preferably by forming a layer of metal on connecting surfaces between the multiple seed crystal structures 104 and the second substrate layer 109 by evaporation or sputtering, and then electroplating a layer of metal on the second substrate layer material as the second substrate layer 109. Alternatively, another substrate may be bonded on the metal surface to form a composite second substrate layer 109, or the second substrate layer 109 may be directly bonded on the multiple seed crystal structures 104 of the connecting surfaces.

Step 4.32, with reference to FIG. 6f, removing the support substrate 107 from the second functional layer 113 by using an immersion method to complete a process of the semiconductor film lifting-off and the substrate transfer.

Specifically, the semiconductor film layer 105 with the support substrate 107 and the second substrate layer 109 is soaked in a solvent to dissolve the adhesive, remove the support substrate 107 to restore the second functional layer 113, thereby obtaining a semiconductor film device with the second substrate layer 109 after the semiconductor film lifting-off and substrate transfer. The process of removing the support substrate 107 may be to heat the second substrate layer 109, heat the support substrate 107, or heat the second substrate layer 109 and the support substrate 107 at the same time.

The solvent can be one or a combination selected from a group consisting of organic solvent, phosphoric acid, nitric acid, hydrogen peroxide, sulfuric acid, potassium hydroxide, sodium hydroxide, ammonia, acidic solution and alkaline solution. The process of dissolving can be a single solvent and/or multiple types of solvents carried out alternately and/or periodically in a certain order.

In actual use, the part of the second substrate layer with the multiple third opening regions can be removed, and the rest without the multiple third opening regions can be reserved for further preparation or use of the required device.

In the description of the disclosure, the terms “first” and “second” are only used for descriptive purposes and cannot be understood as indicating or implying relative importance or implicitly indicating the number of indicated technical features. Thus, the features defining “first” and “second” may explicitly or implicitly include one or more of the features. In the description of the disclosure, “multiple” means two or more, unless otherwise specifically defined.

In the disclosure, unless otherwise expressly specified and limited, a first feature “above” or “below” of a second feature may include direct contact between the first and second features, or the first and second features may not be in direct contact, but through another feature contact between them. Moreover, the first feature is “above”, “upper” and “top” of the second feature, including that the first feature is directly above and obliquely above the second feature, or only indicates that the horizontal height of the first feature is higher than the second feature. The first feature is “below”, “under” and “bottom” of the second feature, including that the first feature is directly below and obliquely below the second feature, or only indicates that the horizontal height of the first feature is less than that of the second feature.

The above is a further detailed description of the disclosure in combination with specific preferred embodiments, and it cannot be determined that the specific implementation of the disclosure is limited to these descriptions. For those skilled in the technical field to which the disclosure belongs, several simple deduction or replacement can be made without departing from the concept of the disclosure, which shall be deemed to belong to the protection scope of the disclosure.

What is claimed is:

1. A method for semiconductor film lift-off and substrate transfer, comprising:
preparing a semiconductor film-substrate structure, wherein the semiconductor film-substrate structure comprises a first substrate layer, a plurality of seed crystal structures and a semiconductor film layer stacked in that order, and holes are formed among the plurality of seed crystal structures and communicated with one another;
lifting-off the plurality of seed crystal structures and the semiconductor film layer from the first substrate layer; and
bonding a side of the plurality of seed crystal structures facing away from the semiconductor film layer with a second substrate layer.

2. The method according to claim 1, wherein the preparing a semiconductor film-substrate structure comprises:
selecting the first substrate layer;
preparing the plurality of seed crystal structures on the first substrate layer; and
growing the semiconductor film layer on the plurality of seed crystal structures.

3. The method according to claim 2, wherein the preparing the plurality of seed crystal structures on the first substrate layer comprises:
forming a plurality of convex structures and a plurality of concave structures on a surface of the first substrate layer;
growing an epitaxial layer with a smooth surface on a side of the first substrate layer having the plurality of convex structures; and
removing the epitaxial layer above each of the plurality of concave structures on the first substrate layer until the first substrate layer being exposed, while retaining at least a part of the epitaxial layer above each of the plurality of convex structures on the first substrate layer, to thereby form the plurality of seed crystal structures.

4. The method according to claim 3, wherein the forming a plurality of convex structures and a plurality of concave structures on a surface of the first substrate layer comprises:
growing a mask layer on the first substrate layer;
performing exposure, development and etching onto the mask layer as per a preset pattern, to expose a part of the surface of the first substrate layer; and
etching the exposed part of the surface of the first substrate layer to form the plurality of convex structures and the plurality of concave structures on the surface of the first substrate layer.

5. The method according to claim 1, wherein the lifting-off the plurality of seed crystal structures and the semiconductor film layer from the first substrate layer comprises:
using a chemical etching method to lift-off the plurality of seed crystal structures and the semiconductor film layer from the first substrate layer.

6. The method according to claim 5, wherein the using a chemical etching method to lift-off the plurality of seed crystal structures and the semiconductor film layer from the first substrate layer comprises:
forming a plurality of first opening regions in the semiconductor film layer, wherein the plurality of first opening regions are communicated with the holes;
disposing a support substrate onto the semiconductor film layer, wherein the support substrate is disposed with a plurality of second opening regions respectively communicated with the plurality of first opening regions; and
injecting a corrosive liquid into the holes among the plurality of seed crystal structures through the plurality of first opening regions and the plurality of second opening regions to thereby strip-off the plurality of seed crystal structures and the semiconductor film layer from the first substrate layer.

7. The method according to claim 6, wherein before the strip-off the plurality of seed crystal structures and the semiconductor film layer from the first substrate layer further comprises:
growing a first functional layer on the semiconductor film layer, wherein the first functional layer is disposed with a plurality of fourth opening regions, and the plurality of fourth opening regions are communicated with the plurality of first opening regions respectively.

8. The method according to claim 5, wherein the using a chemical etching method to lift-off the plurality of seed crystal structures and the semiconductor film layer from the first substrate layer comprises:
adhering a support substrate to the semiconductor film layer;
etching a plurality of third opening regions on a side of the first substrate layer facing away from the plurality of seed crystal structures, wherein the plurality of third opening regions are respectively communicated with the holes; and
injecting a corrosive liquid into the holes among the plurality of seed crystal structures through the plurality of third opening regions to thereby lift-off the plurality of seed crystal structures and the semiconductor film layer from the first substrate layer.

9. The method according to claim 8, wherein before the lifting-off the plurality of seed crystal structures and the semiconductor film layer from the first substrate layer further comprises:
growing a second functional layer on the semiconductor film layer.

10. The method according to claim 6, wherein the bonding a side of the plurality of seed crystal structures facing away from the semiconductor film layer with a second substrate layer comprises:
adhering the side of the plurality of seed crystal structures facing away from the semiconductor film layer to the second substrate layer; and
removing the support substrate by using an immersion method.

11. The method according to claim 7, wherein the bonding a side of the plurality of seed crystal structures facing away from the semiconductor film layer with a second substrate layer comprises:
adhering the side of the plurality of seed crystal structures facing away from the semiconductor film layer to the second substrate layer; and
removing the support substrate by using an immersion method.

12. The method according to claim 8, wherein the bonding a side of the plurality of seed crystal structures facing away from the semiconductor film layer with a second substrate layer comprises:
adhering the side of the plurality of seed crystal structures facing away from the semiconductor film layer to the second substrate layer; and
removing the support substrate by using an immersion method.

13. The method according to claim 9, wherein the bonding a side of the plurality of seed crystal structures facing away from the semiconductor film layer with a second substrate layer comprises:
adhering the side of the plurality of seed crystal structures facing away from the semiconductor film layer to the second substrate layer; and
removing the support substrate by using an immersion method.
